(19) United States
(12) Patent Application Publication
(10) Pub. No.: US 2018/0334743 A1
(43) Pub. Date: Nov. 22, 2018

(54) DIFFUSED CENTER GAS INJECTION COOLING PLATE FOR MEDIA COOLING

(71) Applicant: Seagate Technology LLC, Cupertino, CA (US)

(72) Inventors: Samuel Lewis TANAKA, San Leandro, CA (US); Daniel James GARGAS, San Francisco, CA (US)

(21) Appl. No.: 15/600,626

(22) Filed: May 19, 2017

(51) Int. Cl. C23C 14/58; C23C 14/56; C23C 16/455; C23C 16/46; G11B 33/14

(52) U.S. Cl. CPC C23C 14/5806; C23C 14/568; C23C 14/34; C23C 16/463; G11B 33/142; C23C 16/45572

(57) ABSTRACT

An apparatus includes a cooling plate with a central opening. The central opening within the cooling plate is positioned to be opposite an opening in a workpiece when the cooling plate is positioned at a target location opposite the workpiece. The cooling plate is configured to absorb heat from a gas heated by the workpiece. A diffuser is in the central opening of the cooling plate. The diffuser is configured to receive a gas from a gas input. The diffuser is further configured to slow a flow of the gas and output the gas into the workpiece opening.

### BACKGROUND

During the manufacture of media (e.g. heat assisted magnetic recording (“HAMR”) media), a carrier moves a workpiece between stations which form layers on the workpiece to create the finished media. Some stations heat the workpiece (e.g. during sputtering processes) and the workpiece undergoes cooling before further processing. After the workpiece is cooled, it proceeds to further processing. For example, a carrier may move a workpiece being manufactured into a first station which is a sputtering chamber where a layer is deposited on the workpiece. The sputtering process heats the workpiece, and the carrier transports the workpiece to a cooling station. In the cooling station, heat is absorbed from the workpiece and the workpiece is cooled.

### SUMMARY

Provided herein is an apparatus including a cooling chamber. A carrier is configured to position a workpiece at a target location within the cooling chamber. The workpiece includes an inner diameter, and outer diameter, and a workpiece opening at the inner diameter. A first cooling plate includes a first cooling plate central opening. The first cooling plate central opening is positioned opposite the workpiece opening when the workpiece is positioned at the target location. A first diffuser is in the first cooling plate central opening. The first diffuser is configured to reduce a first velocity of a first gas from a first gas input to the workpiece opening. A second cooling plate includes a second cooling plate central opening. The second cooling plate central opening is positioned opposite the workpiece opening and the first cooling plate central opening when the workpiece is positioned at the target location. A second diffuser is in the second cooling plate central opening. The second diffuser is configured to reduce a second velocity of a second gas from a second gas input to the workpiece opening.

Also provided herein is an apparatus including a cooling plate with a central opening. The central opening within the cooling plate is positioned to be opposite an opening in a workpiece when the cooling plate is positioned at a target location opposite the workpiece. The cooling plate is configured to absorb heat from a gas heated by the workpiece. A diffuser is in the central opening of the cooling plate. The diffuser is configured to receive a gas from a gas input. The diffuser is further configured to slow a flow of the gas and output the gas into the workpiece opening.

Also provided herein is an apparatus including a first diffuser within a first cooling plate. A second diffuser is within a second cooling plate. The second diffuser is positioned opposite the first diffuser. A first gas input is in the first cooling plate. The first gas input injects a first gas through the first diffuser and into an open space between the first diffuser and the second diffuser. A second gas input is in the second cooling plate. The second gas input injects a second gas through the second diffuser and into the open space between the first diffuser and the second diffuser. The first cooling plate and the second cooling plate are positioned to permit a flow of a mixture of the first gas and the second gas from an inner diameter of the first and second cooling plates to an outer diameter of the first and second cooling plates.

These and other features and advantages will be apparent from a reading of the following detailed description.

### BRIEF DESCRIPTION OF DRAWINGS

FIGS. 1A and 1B show a cooling plate according to one aspect of the present disclosure.

FIG. 2 shows a carrier for positioning a workpiece according to one aspect of the present disclosure.

FIG. 3 shows a cross section of the workpiece between a first cooling plate and a second cooling plate according to one aspect of the present disclosure.

FIG. 4 shows a figurative representation of efficient gas flow cooling according to one aspect of the present disclosure.

### DESCRIPTION

Before various embodiments are described in greater detail, it should be understood that the embodiments are not limiting, as elements in such embodiments may vary. It should likewise be understood that a particular embodiment described and/or illustrated herein has elements which may be readily separated from the particular embodiment and optionally combined with any of several other embodiments or substituted for elements in any of several other embodiments described herein.

It should also be understood that the terminology used herein is for the purpose of describing the certain concepts, and the terminology is not intended to be limiting. Unless defined otherwise, all technical and scientific terms used herein have the same meaning as commonly understood in the art to which the embodiments pertain.

Unless indicated otherwise, ordinal numbers (e.g., first, second, third, etc.) are used to distinguish or identify different elements or steps in a group of elements or steps, and do not supply a serial or numerical limitation on the elements or steps of the embodiments thereof. For example, “first,” “second,” and “third” elements or steps need not necessarily appear in that order, and the embodiments thereof need not necessarily be limited to three elements or steps. It should also be understood that, unless indicated otherwise, any labels such as “left,” “right,” “front,” “back,” “top,” “middle,” “bottom,” “beside,” “forward,” “reverse,” “overlying,” “underlying,” “up,” “down,” or other similar terms such as “upper,” “lower,” “above,” “below,” “under,” “between,” “over,” “vertical,” “horizontal,” “proximal,” “distal,” and the like are used for convenience and are not intended to imply, for example, any particular fixed location, orientation, or direction. Instead, such labels are used to reflect, for example, relative location, orientation, or directions. It should also be understood that the singular forms of “a,” “an,” and “the” include plural references unless the context clearly dictates otherwise.

Terms such as “over,” “overlying,” “above,” “under,” etc. are understood to refer to elements that may be in direct contact or may have other elements in-between. For example, two layers may be in overlying contact, wherein one layer is over another layer and the two layers physically contact. In another example, two layers may be separated by one or more layers, wherein a first layer is over a second layer and one or more intermediate layers are between the first and second layers, such that the first and second layers do not physically contact.

A disk drive media manufacturing process may include a carrier that moves a workpiece between stations. As the workpiece moves through the stations on the carrier, the workpiece may move in and out of chambers in which a number of processes form various layers on the workpiece to create the media. Some of the processes (e.g. sputtering processes) heat the workpiece. After the workpiece is heated, it may move to another station where the workpiece undergoes cooling before further processing. Cooling processes may use cooling plates on one or both sides of the workpiece to absorb heat and cool the workpiece. After the workpiece is cooled, it proceeds for further processing.

For example, a carrier may move a workpiece being manufactured into a first station. The first station may be a sputtering chamber where a layer is deposited on the workpiece. The sputtering process heats the workpiece, and the carrier transports the workpiece to a cooling station and into a cooling chamber. In the cooling chamber, the workpiece is positioned near one or more cooling plates, which absorb the heat and cool the workpiece.

According to some embodiments, a gas is injected through a diffuser in a cooling plate. The diffuser slows the velocity of the gas and reduces the pressure of the gas as it is injected into the cooling chamber. In addition, the diffuser in the cooling plate is positioned such that it aligns with an opening in the workpiece at an inner diameter of the workpiece. As a result, when the gas is injected through the diffuser into the cooling chamber, it is not injected directly onto the workpiece.

After the gas is injected, it travels from a higher pressure area at the inner diameter of the workpiece to a lower pressure area at the outer diameter of the workpiece. As the gas travels, it bounces from the workpiece, where the gas absorbs heat, to the cooling plate, where the gas is cooled. Therefore, the gas efficiently cools the workpiece by transferring heat from the workpiece to the cooling plate. As will be described in detail below, such a movement of the gas increases the efficiency of heat transfer by minimizing collisions between the gas particles and maximizing collisions between the gas and the workpiece, as well as between the gas and the cooling plate.

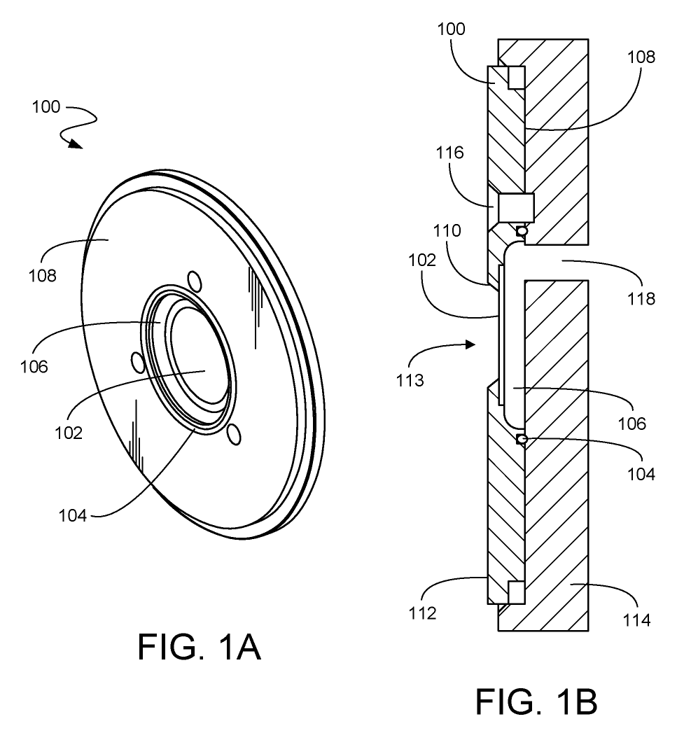

Referring now to FIGS. 1A and 1B, a cooling plate 100 is shown according to one aspect of the present disclosure. The cooling plate 100 includes a diffuser 102 and an o-ring 104. In the illustrated embodiment, the cooling plate 100, the diffuser 102, and the o-ring 104 are annular. The diffuser 102 is located in a first recess 106 (e.g. a recessed pocket) at the center of a first side 108 of the cooling plate 100. The o-ring 104 is also located on the first side 108 of the cooling plate 100 and surrounds the diffuser 102 and the first recess 106.

A second recess 110 is located opposite the first recess 106 at the center of a second side 112 of the cooling plate 100. The diffuser 102 is positioned in the cooling plate 100 at a central opening 113 between the first recess 106 and the second recess 110. The diameter of the diffuser 102 is smaller than the diameter of the first recess 106 and larger than the diameter of the second recess 110.

In various embodiments, the cooling plate, diffuser, o-ring, first recess, and second recess may be any shape, including regular and irregular shapes. In addition, various embodiments may include a diffuser with a diameter larger than or equal to the diameter of the first recess. Various embodiments may also include a diffuser with a diameter smaller than or equal to the diameter of the second recess. As such, any combination of first recess size and shape, diffuser size and shape, and second recess size and shape may be used.

The cooling plate 100 is secured to a backplate 114 with one or more fasteners 116 (e.g. bolt, screw, rivet, pin, nail, stud, etc.). In some embodiments, the cooling plate 100 may be secured to the backplate 114 with any method including (but not limited to): an adhesive, pressfitting the cooling plate 100 and backplate 114 together, screwing the cooling plate 100 and backplate 114 together, welding the cooling plate 100 and backplate 114 together etc. The backplate 114 transfers and removes heat from the cooling plate 100. Any method may be used to remove heat from the backplate 114. For example, in various embodiments the backplate 114 may include ducts through which air and/or water move.

The backplate 114 includes a gas injection conduit 118 that connects to the first recess 106 at an outer diameter of the first recess 106. In various embodiments, the gas injection conduit 118 may connect to the first recess 106 in any location (e.g. an inner diameter of the first recess 106, the middle of the first recess 106, etc.). As such, the gas injection conduit 118 and/or the first recess 106 function as a gas input that delivers gas to the diffuser 102.

The o-ring 104 surrounds the diffuser 102 and the gas input, including the gas injection conduit 118 and the first recess 106. The o-ring 104 prevents the gas that is delivered to the diffuser 102 from escaping between the gas input and the diffuser 102. For example, the o-ring 104 prevents the gas from escaping between the cooling plate 100 and the backplate 114 by sealing the cooling plate 100 to the backplate 114.

In various embodiments, the gas enters the injection conduit 118 and the first recess 106 at a relatively higher pressure and higher velocity. As the gas passes through the diffuser 102, the diffuser 102 lowers the pressure and velocity of the gas. The lower pressure and lower velocity gas then enters the second recess 110 on the other side of the diffuser 102. Therefore, it is understood that the gas in the injection conduit 118 and the first recess 106 is a relatively higher pressure and velocity than the gas in the second recess 110, which is a relatively lower pressure and velocity. In various embodiments the diffuser may be any porous or permeable material that slows the velocity of the gas and/or lowers the pressure of the gas as the gas passes through the diffuser.

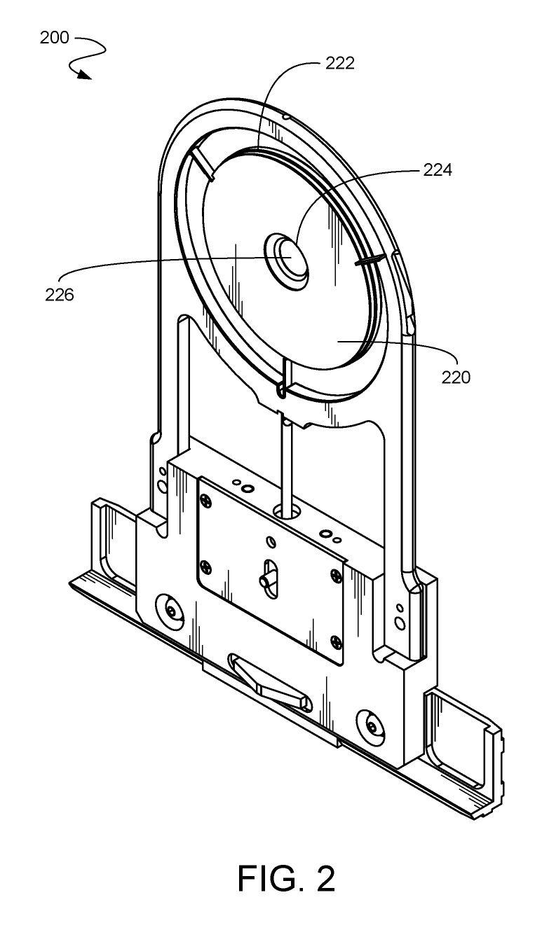

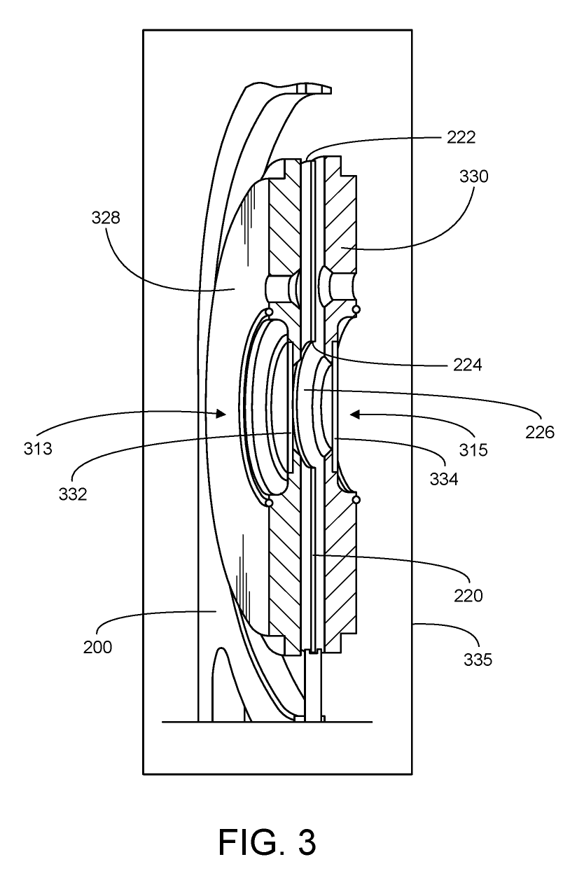

Referring now to FIG. 2, a carrier 200 for positioning a workpiece 220 is shown according to one aspect of the present disclosure. The carrier 200 positions the workpiece 220 with respect to one or more of the cooling plates (see FIG. 3). In various embodiments, the workpiece 220 may be media (e.g. heat assisted magnetic recording (“HAMR”) media) at various stages of manufacture. The workpiece 220 includes an outer diameter 222, an inner diameter 224, and an opening 226 in the workpiece 220 at the inner diameter 224. In some embodiments, the opening 226 may be anywhere in the workpiece 220 and more than one of the openings 226 may be present.

Referring now to FIG. 3, a cross section of the workpiece 220 between a first cooling plate 328 and a second cooling plate 330 is shown according to one aspect of the present disclosure. The first cooling plate 328 and the second cooling plate 330 are similar to the cooling plate 100 in FIG. 1. However, for clarity of illustration, other supporting structures (e.g. the backplate 114, the gas injection conduit 118, etc.) are not shown, but understood to be present. Therefore, it is understood that a first gas input in the first cooling plate 328 injects a first gas through a first diffuser 332 in a central opening 313 of the first cooling plate 328. In addition, a second gas input in the second cooling plate 330 injects a second gas through a second diffuser 334 in a central opening 315 of the second cooling plate 330.

After passing through the first diffuser 332, the first gas flows into the opening 226 at the inner diameter 224 of the workpiece 220. Likewise, after passing through the second diffuser 334, the second gas flows into the opening 226 at the inner diameter 224 of the workpiece 220. The opening 226 is an open space that the first gas and the second gas can flow into without flowing directly onto a surface of the workpiece 220. As previously discussed, the first diffuser 332 lowers the pressure and/or reduces the velocity of the first gas input to the opening 226 in the workpiece 220. In addition, the second diffuser 334 lowers the pressure and/or reduces the velocity of the second gas input to the opening 226 in the workpiece 220. As will be described in detail below, by lowering the pressure and/or reducing the velocity of the first gas and the second gas, as well as by directing the first gas and the second gas to the opening 226 in the workpiece 220, the first diffuser 332 and the second diffuser 334 induce the first gas and the second gas to flow from the opening 226 in the workpiece 220 at the inner diameter 224 to the outer diameter 222.

After the first gas and the second gas flow into the opening 226 the combined gas then flows between the first cooling plate 328 and a first side of the workpiece 220, as well as between the second cooling plate 330 and a second side of the workpiece 220. As the combined gas flows from a higher pressure at the inner diameter 224 of the workpiece 220 to a lower pressure at the outer diameter 222 of the workpiece 220, the gas cools the workpiece 220 by transferring heat from the workpiece 220 to the first cooling plate 328 and the second cooling plate 330.

For clarity of illustration, only a portion of the carrier 200 is shown in FIG. 3 and a figurative representation of a cooling chamber 335 is depicted. The carrier 200 positions the workpiece 220 at a target location within the cooling chamber 335. For example, the carrier 200 may move the workpiece 220 from a sputtering chamber, where the workpiece 220 is heated in a sputtering deposition process, to the cooling chamber 335, where the workpiece 220 is cooled. The target location may be a predetermined location within the cooling chamber 335 between the first cooling plate 328 and the second cooling plate 330.

In some embodiments, the target position is also a position where the first cooling plate 328 and the second cooling plate 330 move to in order to cool the workpiece 220. For example, the first cooling plate 328 and the second cooling plate 330 may move further apart while the workpiece 220 is moving into and out of the cooling chamber 335. When the workpiece 220 is positioned at the target location by the carrier 200, the first cooling plate 328 and the second cooling plate 330 may then move closer together to also position at the target location and closer to the workpiece 220.

At the target location, the central opening 313 in the first cooling plate 328, the central opening 315 in the second cooling plate 330, and the opening 226 in the workpiece 220 are all aligned, thereby creating an open space between the first diffuser 332 and the second diffuser 334. As a result of the alignment, the central opening 313 in the first cooling plate 328 is positioned opposite the opening 226 in the workpiece 220 when the workpiece 220 is positioned at the target location. In addition, as a result of the alignment, the central opening 315 in the second cooling plate 330 is positioned opposite the opening 226 in the workpiece 220 when the workpiece 220 is positioned at the target location. Furthermore, as a result of the alignment and positioning of the first cooling plate 328, the second cooling plate 330, and the workpiece 220 at the target location, the first diffuser 332 and the second diffuser 334 are positioned opposite each other.

In various embodiments, the first cooling plate 328 and the second cooling plate 330 include outer diameters. In addition, the first cooling plate 328 and the second cooling plate 330 include inner diameters at the central opening 313 and the central opening 315. As such, when the first cooling plate 328 and the workpiece 220 are positioned at the target location, the first diffuser 332 causes the first gas to flow from the inner diameter at the central opening 313 to the outer diameter of the first cooling plate 328. In addition, when the second cooling plate 330 and the workpiece 220 are positioned at the target location, the second diffuser 334 causes the second gas to flow from the inner diameter at the central opening 315 to the outer diameter of the second cooling plate 330.

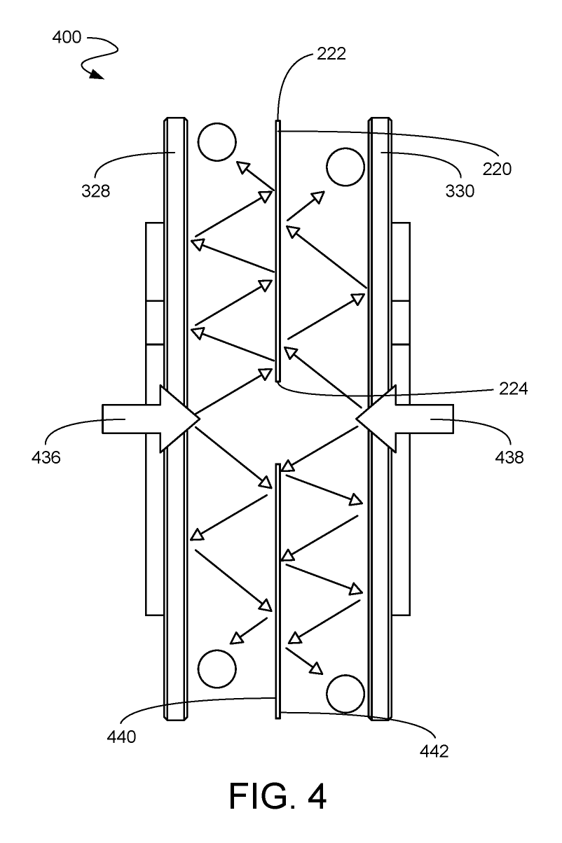

Referring now to FIG. 4, a figurative representation 400 of efficient gas flow cooling is shown according to one aspect of the present disclosure. In various embodiments, the first gas 436 and the second gas 438 may be the same gas or different gasses. For example, the first gas 436 and/or the second gas 438 may be helium, argon, nitrogen, or other gasses. In addition, the first gas 436 and/or the second gas 438 may be combination of gasses. In some embodiments, the first gas 436 and/or the second gas 438 are essentially free of contaminants.

As discussed above, the first gas 436 and the second gas 438 are injected through the first diffuser 332 and the second diffuser 334 into the open space between the first diffuser 332 and the second diffuser 334. Therefore, the first diffuser 332 and the second diffuser 334 are positioned to direct the injection of the first gas 436 and the second gas 438 to not directly inject onto a surface of the workpiece 220 when the workpiece 220 is positioned at the predetermined location between the first cooling plate 328 and the second cooling plate 330.

The first gas 436 and the second gas 438 mix and combine in the open space between the first diffuser 332 and the second diffuser 334. The gas then flows from the inner diameter 224 of the workpiece 220 to the outer diameter 222 of the workpiece 220. As the gas flows it bounces back and forth between a first side 440 of the workpiece 220 and the first cooling plate 328, thereby transferring heat from the workpiece 220 to the first cooling plate 328. In addition, as the gas bounces back and forth between a second side 442 of the workpiece 220 and the second cooling plate 330, thereby transferring heat from the workpiece 220 to the second cooling plate 330.

The movement of the gas from the higher pressure at the inner diameter 224 to the lower pressure at the outer diameter 222 minimizes or eliminates collisions between gasses. As a result, the gas directly transfers heat from the workpiece 220 to the first cooling plate 328 and the second cooling plate 330. For example, helium may absorb heat from the workpiece 220 and then carry the heat to the first cooling plate 328. After transferring the heat to the first cooling plate 328, the helium bounces back to the workpiece 220, where the helium absorbs more heat. The movement of the helium from the higher pressure at the inner diameter 224 to the lower pressure at the outer diameter 222 allows the helium to cool the workpiece 220 without excessive helium to helium collisions.

Without the gas movement, collisions between gasses would increase and heat would transfer between gasses before reaching the cooling plates. For example, helium absorbs heat from the workpiece 220. The heated helium then encounters another helium. If the encountered helium is cooler, the heat is transferred. As such heat may or may not be transferred between helium to helium collisions until eventually one of the heated helium encounters the first cooling plate 328 or the second cooling plate 330, where heat is finally removed. Such a static system where the gas does not flow is much less efficient than the dynamic system described in the various embodiments above, describing the flow of gas between the workpiece and one or more cooling plates.

While the embodiments have been described and/or illustrated by means of particular examples, and while these embodiments and/or examples have been described in considerable detail, it is not the intention of the Applicants to restrict or in any way limit the scope of the embodiments to such detail. Additional adaptations and/or modifications of the embodiments may readily appear, and, in its broader aspects, the embodiments may encompass these adaptations and/or modifications. Accordingly, departures may be made from the foregoing embodiments and/or examples without departing from the scope of the concepts described herein. The implementations described above and other implementations are within the scope of the following claims.

What is claimed is:

1. An system comprising:
a cooling chamber;
a carrier configured to position a workpiece at a target location within the cooling chamber, wherein the workpiece includes an inner diameter, and outer diameter, and a workpiece opening at the inner diameter;
a first cooling plate including a first cooling plate central opening, wherein the first cooling plate central opening is positioned opposite the workpiece opening when the workpiece is positioned at the target location;
a first diffuser in the first cooling plate central opening, wherein the first diffuser is configured to reduce a first velocity of a first gas from a first gas input to the workpiece opening;
a second cooling plate including a second cooling plate central opening, wherein the second cooling plate central opening is positioned opposite the workpiece opening and the first cooling plate central opening when the workpiece is positioned at the target location; and
a second diffuser in the second cooling plate central opening, wherein the second diffuser is configured to reduce a second velocity of a second gas from a second gas input to the workpiece opening.

2. The apparatus of claim 1, wherein the carrier is further configured to position the workpiece at the target location after the workpiece has been heated in a sputtering deposition process.

3. The apparatus of claim 1, wherein the first diffuser is further configured to lower a pressure of the first gas.

4. The apparatus of claim 1, wherein the first cooling plate central opening includes a recessed pocket and the first diffuser is positioned within the recessed pocket.

5. The apparatus of claim 1, further comprising an o-ring surrounding the first diffuser and the first gas input, wherein the o-ring prevents the first gas from escaping between the first gas input and the first diffuser.

6. The apparatus of claim 1, wherein the first gas is essentially free of contaminants and includes argon, nitrogen, or helium.

7. The apparatus of claim 1, wherein the first diffuser and the second diffuser induce the first gas and the second gas to flow from the workpiece opening at the inner diameter to the outer diameter.

8. An apparatus comprising:
a cooling plate including a central opening, wherein
the central opening within the cooling plate is positioned to be opposite an opening in a workpiece when the cooling plate is positioned at a target location opposite the workpiece, and
the cooling plate is configured to absorb heat from a gas heated by the workpiece; and
a diffuser in the central opening of the cooling plate, wherein
the diffuser is configured to receive a gas from a gas input, and
the diffuser is further configured to slow a flow of the gas and output the gas into the workpiece opening.

9. The apparatus of claim 8, further comprising a carrier configured to position the workpiece at the target location after the workpiece has been heated in a sputtering deposition process.

10. The apparatus of claim 8, wherein the diffuser is further configured to lower a pressure of the gas.

11. The apparatus of claim 8, wherein the central opening includes a recessed pocket and the diffuser is positioned within the recessed pocket.

12. The apparatus of claim 8, further comprising an o-ring surrounding the diffuser and the gas input, wherein the o-ring prevents the gas from escaping between the gas input and the diffuser.

13. The apparatus of claim 8, wherein the gas is helium.

14. The apparatus of claim 8, wherein
the cooling plate further includes an outer diameter, and
the diffuser causes the gas to flow from the central opening to the outer diameter when the cooling plate is positioned at the target location opposite the workpiece.

15. An apparatus comprising:
a first diffuser within a first cooling plate;
a second diffuser within a second cooling plate, wherein the second diffuser is positioned opposite the first diffuser;
a first gas input in the first cooling plate, wherein the first gas input injects a first gas through the first diffuser and into an open space between the first diffuser and the second diffuser; and
a second gas input in the second cooling plate, wherein
the second gas input injects a second gas through the second diffuser and into the open space between the first diffuser and the second diffuser, and
the first cooling plate and the second cooling plate are positioned to permit a flow of a mixture of the first gas and the second gas from an inner diameter of the first and second cooling plates to an outer diameter of the first and second cooling plates.

16. The apparatus of claim 15, wherein the open space is positioned to be located within an inner diameter of a workpiece, when the workpiece is at a predetermined located between the first cooling plate and the second cooling plate.

17. The apparatus of claim 15, wherein the first diffuser and the second diffuser are positioned to direct the injection of the first gas and the second gas to not directly inject onto a surface of a workpiece when the workpiece is positioned at a predetermined located between the first cooling plate and the second cooling plate.

18. The apparatus of claim 15, wherein the first diffuser is configured to slow a flow of the first gas from the first gas input to the open space between the first diffuser and the second diffuser.

19. The apparatus of claim 15, wherein the first diffuser is configured to lower a pressure of the first gas from the first gas input to the open space between the first diffuser and the second diffuser.

20. The apparatus of claim 15, wherein the first gas and the second gas are the same gas.
